(19) United States
(12) Patent Application Publication
(10) Pub. No.: US 2026/0090388 A1
(43) Pub. Date: Mar. 26, 2026

(54) INTERPOSER SUBSTRATE AND SEMICONDUCTOR PACKAGE INCLUDING INTERPOSER SUBSTRATE

(71) Applicant: Samsung Electronics Co., Ltd., Suwon-si (KR)

(72) Inventors: Hideko Mukaida, Yokohama-shi (JP); Koji Asano, Yokohama-shi (JP); Mitsuhiro Tomikawa, Yokohama-shi (JP); Takashi Kariya, Yokohama-shi (JP)

(21) Appl. No.: 19/227,668

(22) Filed: Jun. 4, 2025

(30) Foreign Application Priority Data
Sep. 24, 2024 (JP) 2024-164793
Dec. 10, 2024 (KR) 10-2024-0182993

(51) Int. Cl. H01L 23/00; H01L 21/56; H01L 23/31; H01L 23/498; H01L 25/00; H01L 25/18; H10B 80/00; H10D 80/30

(52) U.S. Cl. CPC H10W 42/121; H10B 80/00; H10D 80/30; H10W 90/00; H10W 90/701; H10W 72/853; H10W 74/01; H10W 74/114; H10W 74/15; H10W 90/22; H10W 90/722; H10W 90/724; H10W 90/733; H10W 90/734

(57) ABSTRACT

An interposer substrate is provided between a mounting substrate and a semiconductor device. The interposer substrate includes a conductor electrically connecting the mounting substrate and the electronic device; a mechanical member electrically insulated from the mounting substrate, the semiconductor device, and the conductor; and a first resin material provided around the conductor and the mechanical member, wherein the mechanical member has a Young's modulus higher than that of the first resin material.

### CROSS-REFERENCE TO RELATED APPLICATION(S)

This application claims the benefit under 35 USC 119 (a) of Korean Patent Application No. 10-2024-0182993 filed on Dec. 10, 2024 in the Korean Intellectual Property Office and Japanese Patent Application No. 2024-164793 filed on Sep. 24, 2024, in the Japan Patent Office, the entire disclosure of which is incorporated herein by reference for all purposes.

### BACKGROUND

The present inventive concept relates to an interposer substrate and a module or semiconductor package including the interposer substrate.

An electronic device such as a semiconductor chip and a mounting substrate may be connected, for example, by an interposer substrate. The interposer substrate is often also referred to as an interposer. As the development of various interposer substrates progresses, the development of interposer substrates having resin layers is also progressing. In the interposer substrate including such resin layers, it is desirable to suppress warpage.

### SUMMARY

An aspect of the present inventive concept is to provide an interposer substrate and a module for suppressing warpage.

According to an embodiment, a semiconductor package includes an interposer substrate between a mounting substrate and a semiconductor device. The interposer substrate includes: a plurality of conductors electrically connecting the mounting substrate to the semiconductor device; a warpage-suppressing member electrically insulated from the mounting substrate, the semiconductor device, and the plurality of conductors; and a first resin material surrounding the plurality of conductors and the warpage-suppressing member. The warpage-suppressing member has a Young's modulus higher than a Young's modulus of the first resin material.

According to an embodiment, the plurality of conductors is a plurality of conductive vias and the warpage-suppressing member includes a plurality of warpage-suppressing beams or a plurality of warpage-suppressing bars.

According to an embodiment, the first resin material contacts the plurality of conductors and the warpage-suppressing member.

According to an embodiment, the warpage-suppressing member has a Young's modulus of 70 GPa or more.

According to an embodiment, the warpage-suppressing member comprises at least one of ceramic and glass.

According to an embodiment, the ceramic comprises at least one of aluminum oxide, aluminum nitride, and silicon carbide.

According to an embodiment, the warpage-suppressing member extends along at least two sides of the interposer substrate.

According to an embodiment, the plurality of the conductors are arranged side by side in a first direction and a second direction, intersecting the first direction, and the warpage-suppressing member includes a first warpage-suppressing member portion disposed between adjacent rows of the conductors in the first direction and extending in the second direction.

According to an embodiment, the warpage-suppressing member further comprises a second warpage-suppressing member portion disposed between adjacent rows of the conductors in the second direction and extending in the first direction.

According to an embodiment, the warpage-suppressing member is further disposed between adjacent rows of the conductors in the second direction.

According to an embodiment, the semiconductor package further comprises a bridge die between the mounting substrate and the semiconductor device, and electrically connecting the semiconductor device to an additional semiconductor device mounted horizontally adjacent to the semiconductor device.

According to an embodiment, on a predetermined plane parallel to a main surface of the interposer substrate, an area occupied by the warpage-suppressing member is between 0.1% and 50% with respect to an area of the interposer substrate.

According to an embodiment, in a direction perpendicular to the main surface of the interposer substrate, a distance between a top surface and a bottom surface of the warpage-suppressing member is less than or equal to a distance between a top surface and a bottom surface of each conductor.

According to an embodiment, the semiconductor package further comprises a second resin material provided with the semiconductor device.

According to an embodiment, the semiconductor package further comprises a first redistribution layer between the interposer substrate and the mounting substrate and electrically connecting the mounting substrate to the plurality of conductors; and a second redistribution layer between the interposer substrate and the semiconductor device and electrically connecting the semiconductor device to the plurality of conductors.

According to an embodiment, the semiconductor device is a first semiconductor device mounted on the second redistribution layer, and the semiconductor package further comprises a second semiconductor device mounted on the second redistribution layer and horizontally adjacent to the first semiconductor device; and a bridge die mounted on the first redistribution layer and electrically connecting the first semiconductor device to the second semiconductor device.

According to an embodiment, the warpage-suppressing member includes a plurality of warpage-suppressing member portions, each extending along a respective side edge of the interposer substrate.

According to another embodiment, a semiconductor package includes a mounting substrate, a first semiconductor device on the mounting substrate, and an interposer between the mounting substrate and the first semiconductor device. The interposer includes an interposer substrate, a first redistribution layer between the mounting substrate and the interposer substrate, and a second redistribution layer between the first semiconductor device and the interposer substrate. The interposer substrate includes a resin extending between the first redistribution layer and the second redistribution layer, a plurality of conductive vias, each extending from the first redistribution layer to the second redistribution layer, and a warpage-suppressing member including a plurality of elongated portions, each elongated portion extending vertically between the first redistribution layer and the second redistribution layer and extending horizontally along a top surface of the first redistribution layer.

According to an embodiment, the resin is formed of a first material having a first Young's modulus, and the warpage-suppressing member is formed of a second material different from the first material and having a second Young's modulus greater than the first Young's modulus.

According to an embodiment, the warpage-suppressing member is formed of a glass or ceramic material.

According to an embodiment, the plurality of elongated portions are a plurality of beams or a plurality of bars.

According to an embodiment, the semiconductor package further comprises a bridge die mounted on the first redistribution layer within the interposer substrate and electrically connecting the first semiconductor device to a second semiconductor device mounted on the second redistribution layer and horizontally adjacent to the first semiconductor device.

According to an embodiment, the first semiconductor device is a memory chip or stack of memory chips, and the second semiconductor device is a logic device.

According to another embodiment, a semiconductor package comprises an interposer including an interposer substrate, a first redistribution layer on a bottom surface of the interposer substrate, and a second redistribution layer on a top surface of the interposer substrate. The interposer substrate includes a first material layer extending between the first redistribution layer and the second redistribution layer; a plurality of conductive vias, each extending from the first redistribution layer to the second redistribution layer and passing through the first material layer; and a warpage-suppressing member passing through the first material layer and including a plurality of elongated portions, each elongated portion extending vertically between the first redistribution layer and the second redistribution layer and extending horizontally along a top surface of the first redistribution layer. A Young's modulus of the first material layer is lower than a Young's modulus of the warpage-suppressing member.

According to an embodiment, the first material layer is a resin layer; and the warpage-suppressing member is formed of glass or a ceramic material.

According to an embodiment, the top surface of the first redistribution layer faces the bottom surface of the interposer substrate, and the semiconductor package further includes a plurality of connection terminals on a bottom surface of the first redistribution layer opposite the top surface.

According to an embodiment, the semiconductor package further includes a first semiconductor device and a second semiconductor device mounted on the second redistribution layer; and a bridge die embedded in the interposer substrate and electrically connecting the first semiconductor device to the second semiconductor device.

According to an embodiment, wherein the first semiconductor device is a memory chip or stack of memory chips, and the second semiconductor device is a logic device.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view illustrating an example of a configuration of a module according to an example embodiment of the present inventive concept;

FIG. 2 is a drawing illustrating an example of a planar configuration of the resin layer illustrated in FIG. 1;

FIG. 3 is a cross-sectional view illustrating one process of the manufacturing method of the module illustrated in FIG. 1;

FIG. 4 is a cross-sectional view illustrating a process following the process illustrated in FIG. 3;

FIG. 5 is a cross-sectional view illustrating a process following the process illustrated in FIG. 4;

FIG. 6 is a cross-sectional view illustrating a process following the process illustrated in FIG. 5;

FIG. 7 is a cross-sectional view illustrating a process following the process illustrated in FIG. 6;

FIG. 8 is a cross-sectional view illustrating a process following the process illustrated in FIG. 7;

FIG. 9 is a cross-sectional view illustrating a process following the process illustrated in FIG. 8;

FIG. 10 is a drawing illustrating an example of a planar configuration of a resin layer according to a modified example; and

FIG. 11 is a planar drawing illustrating another example of the resin layer illustrated in FIG. 10.

### DETAILED DESCRIPTION

Hereinafter, with reference to the attached drawings, example embodiments of the present inventive concept will be described in detail. In the drawings below, the same reference numerals indicate the same components, and the size of each component in the drawings may be exaggerated for clarity and convenience of explanation. The example embodiments described below are merely exemplary, and various modifications are possible from the example embodiments.

Items described in the singular herein may be provided in plural, as can be seen, for example, in the drawings. Thus, the description of a single item that is provided in plural should be understood to be applicable to the remaining plurality of items unless context indicates otherwise.

Also, throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Also, these spatially relative terms such as “above” and “below” as used herein have their ordinary broad meanings—for example element A can be above element B even if when looking down on the two elements there is no overlap between them (just as something in the sky is generally above something on the ground, even if it is not directly above).

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The three different directions may include a third direction that may be orthogonal to the two different directions. The plurality of device structures may be integrated in a same electronic device.

An item, layer, or portion of an item or layer described as extending “lengthwise” in a particular direction has a length in the particular direction and a width perpendicular to that direction, where the length is greater than the width.

For the steps constituting the method, if the order is explicitly stated or if there is no contrary description, the steps are executed in the appropriate described order. However, the order is not necessarily limited to the order in which the steps are described above. The use of any examples or exemplary terms (e.g., etc.) is intended merely to illustrate technical ideas and is not intended to limit the scope of the invention, unless otherwise limited by the claims.

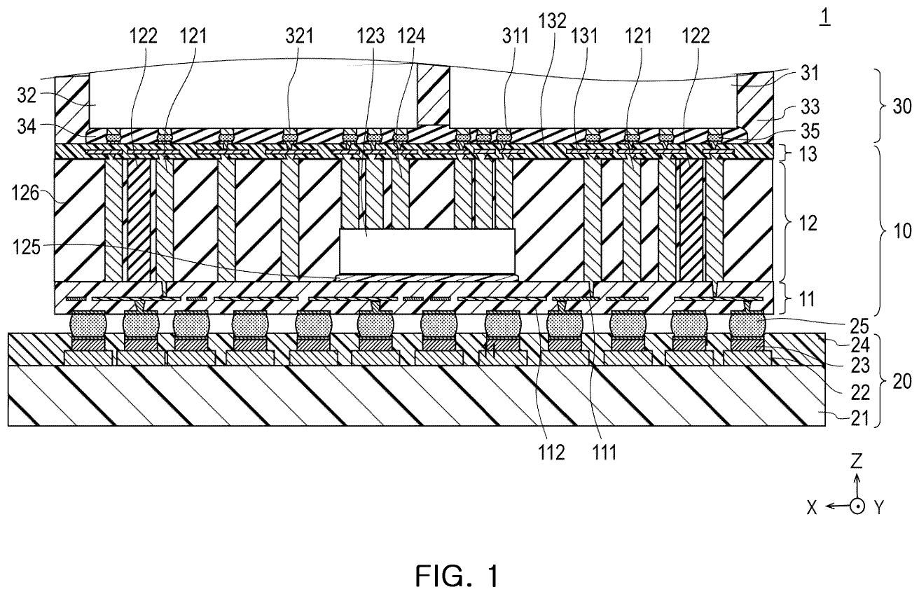

FIG. 1 illustrates an example of a configuration of a module 1 according to an example embodiment of the present inventive concept. The module 1 includes, for example, an interposer substrate 10, a mounting substrate 20, and an electronic device layer 30 as main components. The interposer substrate 10 functions as an interposer connecting the mounting substrate 20 and the electronic device layer 30. The mounting substrate 20 may be disposed at a bottom, the interposer substrate 10 may be disposed above the mounting substrate 20 to be between the mounting substrate 20 and the electronic device layer, and the electronic device layer 30 may be disposed above the interposer substrate 10. In the following descriptions, a direction in which the mounting substrate 20, the interposer substrate 10, and the electronic device layer 30 are arranged in this order may be referred to as a Z-direction, a direction orthogonal to the Z-direction may be referred to as a X-direction, and a direction orthogonal to the Z-direction and the X-direction may be referred to as a Y-direction. Each of these different directions may also be described as first, second, or third directions. A main surface of each of the interposer substrate 10 and the mounting substrate 20 is, for example, an X-Y plane. Here, the X-direction corresponds to one specific example of a first direction of the present inventive concept, and the Y-direction corresponds to one specific example of a second direction of the present inventive concept.

The electronic device layer 30 includes, for example, electronic devices 31 and 32, a sealing material 33, an underfill material 34, and a bump 35. Each of the electronic devices 31 and 32 are, for example, a semiconductor chips having a predetermined function. The electronic devices 31 and 32 are, for example, semiconductor devices such as an Integrated Circuit (IC) chip or memory. For example, in one embodiment, the electronic device 31 is a logic device such as an Application Specific Integrated Circuit (ASIC) and the electronic device 32 is a memory chip or stack of chips, for example, such as a High Bandwidth Memory (HBM). The electronic device 31 has, for example, a plurality of electrodes 311 on a surface opposite to (e.g., facing) the interposer substrate 10 (for example, the X-Y plane). The electronic device 32 has, for example, a plurality of electrodes 321 on the surface opposite to (e.g., facing) the interposer substrate 10 (for example, the X-Y plane). Each electrode may be, for example, a conductive post or conductive pad, formed of a conductive material such as a metal.

Each of the electrodes 311 and 321 is electrically connected to the interposer substrate 10 by a bump 35. For example, a plurality of bumps 35 are provided in the electronic device layer 30. Each bump 35 includes or is formed of, for example, a solder material. The underfill material 34 is provided between the electronic devices 31 and 32 and the interposer substrate 10. For example, a space between the adjacent bumps 35 is filled with an underfill material 34. The underfill material 34 includes, for example, an insulating material such as a resin. The encapsulating material 33 is stacked on the underfill material 34. The encapsulating material 33 covers a peripheral portion of the electronic devices 31 and 32. In one embodiment, the encapsulating material 33 is an insulating material, which may be a resin. In one embodiment, the resin of the encapsulating material 33 maybe a different type of resin from the underfill material 34, and may correspond to a specific example of a second resin material.

The mounting substrate 20 may be, for example, a semiconductor package substrate or a motherboard. The mounting substrate 20 includes, for example, an insulative substrate 21, a wiring layer 22, an electrode 23, and a solder resist layer 24. The mounting substrate 20 may be in the form of a printed circuit board (PCB). The mounting substrate may be, for example, a motherboard that includes internal wiring, such as the wiring layer 22 or another wiring layer not shown, which electrically connects the interposer substrate 10 to another portion of the motherboard (not shown), so that the device including the interposer substrate 10 and the electronic devices 31 and 32 can connect to an external system mounted on the motherboard or to which the motherboard is connected. Alternatively, the mounting substrate may be a package substrate, and may include an internal wiring layer (not shown) connected to a bottom set of external connection terminals (not shown) such as bumps or balls (e.g., solder bumps or solder balls). Therefore, in one embodiment, module 1 represents a semiconductor device or electronic device, such as an interposer having semiconductor chips mounted thereon, mounted on a module board or motherboard. In another embodiment, module 1 represents a semiconductor device or electronic device, such as a semiconductor package including an interposer and semiconductor chips mounted on a package substrate.

In one embodiment, the mounting substrate 20 is electrically connected to the interposer substrate 10 by a plurality of connection terminals 25 such as bumps. The plurality of connection terminals 25 are provided on the electrodes 23. The electrodes may be conductive pads formed of a conductive material such as a metal. The connection terminals 25 may be bumps including, for example, a soldering material.

The interposer substrate 10 may include, for example, a first redistribution layer 11, a resin layer 12, and a second redistribution layer 13. In the interposer substrate 10, for example, from a surface of the mounting substrate 20, a first redistribution layer 11, a resin layer 12, and a second redistribution layer 13 are stacked in ascending order so that the first redistribution layer 11 is between the mounting substrate 20 and the resin layer 12, and the resin layer 12 is between the first redistribution layer 11 and the second redistribution layer 13. In the first redistribution layer 11, for example, a wiring 111 and an insulating material 112 are provided. In the resin layer 12, for example, pillar electrodes 121 and 124, a mechanical member 122, an electronic component 123, an adhesive layer 125, and a resin material 126 are provided. In the second redistribution layer 13, for example, a wiring 131 and an insulating material 132 are provided. The pillar electrode 121 may be a conductor, or conductive via, and the resin material 126 may be an insulating layer that surrounds the pillar electrodes 121 and 124 as well as the electronic component 123.

In the first redistribution layer 11, for example, a plurality of wirings 111 are provided. For example, the electrode 23 and the pillar electrode 121 are electrically connected by the wirings 111, for example through other conductive components therebetween. For example, an electrode 23 and an electronic component 123 are electrically connected by a wiring 111, for example through other conductive components therebetween. A plurality of wirings 111 are embedded in an insulating material 112. In one embodiment, each wiring 111 includes a conductive metal material such as, for example, gold, platinum, palladium, silver, copper, aluminum, cobalt, titanium, chromium, nickel, tungsten, iron, tin, indium or zinc. The insulating material 112 may include an organic insulating material such as, for example, epoxy resin, phenol resin and acrylic resin.

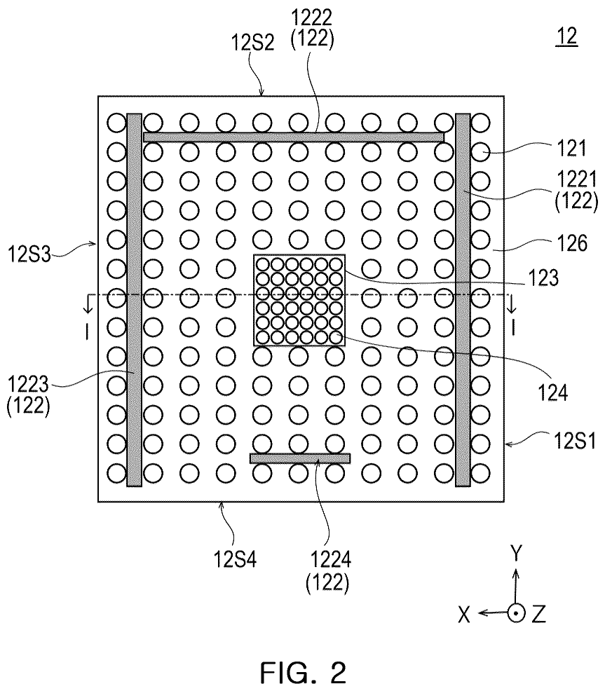

FIG. 2 illustrates an example of a configuration of a plane (XY plane) of a resin layer 12. The resin layer 12 illustrated in FIG. 1 corresponds to a cross-sectional configuration taken along the I-I line illustrated in FIG. 2. The resin layer 12 has, for example, a rectangular planar shape which in one embodiment may be a square shape. The resin layer 12 has, for example, sides 12S1 and sides 12S3 extending in the Y-direction, and sides 12S2 and sides 12S4 extending in the X-direction. The electronic component 123 is, for example, disposed in a central portion of a region of the resin layer 12 defined by the sides (12S1, 12S2, 12S3, 12S4). In some embodiments, the electronic component may be in the exact center of the region of the resin layer 12 defined by the sides (12S1, 12S2, 12S3, 12S4). A plurality of pillar electrodes 124 are, for example, disposed overlapping the electronic component 123 when viewed from a plan view. The plurality of pillar electrodes 121 are disposed side by side around the electronic component 123, for example, in the X-direction and the Y-direction respectively. In one embodiment, the plurality of pillar electrodes 121 are disposed in a matrix form. The mechanical member 122 is disposed in the peripheral portion of the resin layer 12. For example, a plurality of portions of the mechanical member 122 are provided in the resin layer 12. For example, the portions of the mechanical member 122 include a first mechanical member portion 1221, a second mechanical member portion 1222, a third mechanical member portion 1223 and a fourth mechanical member portion 1224. Each mechanical member portion may be a support or support structure, which may be for example a warpage-suppressing bar or warpage-suppressing beam. The mechanical member portions together may form a group of beams or bars that form a beam structure or bar structure, such as a frame or fence within the resin 12. The beams or bars may be connected to or separate from each other. The warpage-suppressing member 122 may therefore include a plurality of elongated portions, each elongated portion extending vertically between the first redistribution layer 11 and the second redistribution layer 13 and extending horizontally, for example, along a side edge of the interposer substrate 10. The mechanical member 122 may be a warpage-suppressing frame or foundation for the semiconductor device. The mechanical member 122 may be formed of a rigid material, and example materials for the mechanical member 122 are described further below.

The resin material 126 provided around the pillar electrodes 121 and 124 and the mechanical member 122 is an insulating resin material. The resin material 126 includes, for example, one or more of an epoxy resin, phenol resin, acrylic resin, polyimide resin, and liquid crystal polymer. The resin material 126 may include an additional filler. The resin material 126 (e.g., either with or without an additional filler) may have a Young's modulus of, for example, 100 MPa to 10,000 MPa. As compared to the case of using an inorganic material or silicon (Si), by using the resin material 126, it is possible to improve the electrical characteristics of the interposer substrate 10 and also suppress the cost.

The pillar electrodes 121 and 124 extend in a Z-direction (e.g., vertically). A height (a distance from the bottom surface to the top surface in the Z-direction) of each of the pillar electrodes 121 is the same as or substantially the same as a thickness of the resin layer 12. The thickness (a distance from the bottom surface to the top surface in the Z-direction) of the resin layer 12 is, for example, about 50 μm to 200 μm in some embodiments. The thickness of the resin layer 12 is, for example, smaller than the thickness (in the Z-direction) of the electronic device layer 30 in some embodiments. The pillar electrode 121 electrically connects the wiring 111 and the wiring 131.

The height (a distance from the bottom surface to the top surface in the Z-direction) of the pillar electrode 124 is, for example, smaller than the height of the pillar electrode 121. For example, one end of the pillar electrode 124 in the Z-direction is in contact with the electronic component 123. The pillar electrode 124 electrically connects the electronic component 123 and the wiring 131. The electronic component 123 may be, for example, a die such as a bridge die, that electrically connects the electronic device 31 to the electronic device 32, for example, through the pillar electrodes 124 and the wiring 131.

The pillar electrodes 121 and 124 include, or consist of, for example, copper (Cu). The pillar electrodes 121 and 124 may be conductive vias, passing through the resin layer 12. In some embodiments, the pillar electrodes 121 and 124 are formed prior to the formation of the resin material 126. In other embodiments, other conductive vias, such as through-resin vias may be formed in the resin material 126 after the resin material is formed (e.g., by forming an opening passing through the resin material 126). A combination of pillar electrodes and through-resin vias may be used.

The mechanical member 122 is disposed in the vicinity of (e.g., adjacent to) each of the sides 12S1, 12S2, 12S3, and 12S4. In the vicinity of the sides 12S1 and 12S3, for example, a first mechanical member 1221 and a third mechanical member 1223, each of which extends along the sides 12S1 and 12S3, are provided. The first mechanical member 1221 and the third mechanical member 1223 are disposed between adjacent pillar electrodes 121 in the X-direction (e.g., between adjacent rows of pillar electrodes 121 in the X-direction). In the vicinity of the side 12S2, a second mechanical member 1222 extending along the side 12S2 is provided. This second mechanical member 1222 is disposed between adjacent pillar electrodes 121 in the Y-direction (e.g., between adjacent rows of pillar electrodes 121 in the Y-direction). In the vicinity of the side 12S4, a fourth mechanical member 1224 is provided in a selective region of a central portion of the side 12S4. This fourth mechanical member 1224 is disposed between the adjacent pillar electrodes 121 in the Y-direction.

The mechanical member 122 is configured to be electrically insulated from each of the mounting substrate 20, the electronic element layer 30, the pillar electrodes 121 and 124, and the electronic component 123. Therefore, the mechanical member 122 exists electrically independently of an electronic circuit within the module 1. According to some embodiments, the mechanical member 122 has insulating properties. For example, in some embodiments, the electrical resistance of the mechanical member 122 is 106 ohm or more.

The mechanical member 122 has a Young's modulus higher than that of the resin material 126. The Young's modulus of the mechanical member 122 may be the Young's modulus of the material that forms the mechanical member 122. In the present embodiment, since the mechanical member 122 is provided in the resin layer 12, the influence of internal stress in the resin layer 12 is reduced, as compared to the case in which the mechanical member 122 is not provided in the resin layer 12. Details thereof will be described later, but accordingly, warpage of the interposer substrate 10 may be suppressed. The mechanical member 122 may therefore be a warpage-suppressing member.

For example, according to some embodiments, the mechanical member 122 is comprised of or consists of one or more materials having a Young's modulus higher than that of the resin material 126. In some embodiments, the mechanical member 122 has, for example, a Young's modulus of 20 GPa or more, and in some embodiments 70 GPa or more (e.g., between 20 GPa and 400 GPa and in some embodiments, between 70 GPa and 400 GPa, or between 20 GPa and 90 GPa, or any other sub-ranges of GPa that correspond to the possible Young's Moduli of one of the below example materials or a group of the below example materials). In some embodiments, the mechanical member 122 includes or consists of at least one of ceramic and glass. The ceramic may contain, for example, at least one of aluminum oxide (Al₂O₃), aluminum nitride (AlN), and silicon carbide (SiC). In the mechanical member 122 including ceramic or glass, good insulation and elasticity may be realized. The mechanical member 122 may be formed by, for example, mold forming and laser processing.

On a predetermined plane parallel to a main surface of the interposer substrate 10, in some embodiments, an area occupied by the mechanical member 122 is 0.1% or more with respect to an area of the interposer substrate 10. A predetermined plane parallel to the main surface of the interposer substrate 10 is, for example, an X-Y cross-section of the interposer substrate 10 in a portion in which the mechanical member 122 exists. For example, in one embodiment, a predetermined X-Y cross-section (see FIG. 2) of the interposer substrate 10, the sum of the areas of the X-Y planes of each of the four mechanical members 122 is 0.1%, with respect to the area of the interposer substrate 10. Accordingly, the mechanical member 122 may function efficiently, and may more effectively suppress warpage of the interposer substrate 10. In some embodiments, in a predetermined plane parallel to the main surface of the interposer substrate 10, the area occupied by the mechanical member 122 with respect to the area of the interposer substrate 10 is, for example, 0.1% or more and 90% or less, and may be in some embodiments, between 0.1% and 50%, between 0.5% and 20%, or 0.5% and 10%. By setting the area occupied by the mechanical member 122 to 90% or less, the function of the interposer substrate 10 may be maintained.

A distance from a top surface to a bottom surface of the mechanical member 122 in a Z-direction is, for example in one embodiment, the same or substantially the same as the thickness of the resin layer 12. In addition, in some embodiments, the distance from a top surface to a bottom surface of the mechanical member 122 in the Z-direction is the same or substantially the same as the height from a top surface to a bottom surface of the pillar electrode 121. The distance from a top surface to a bottom surface of the mechanical member 122 in the Z-direction may be less than or equal to the thickness of the resin layer 12. For example, the distance from a top surface to a bottom surface of the mechanical member 122 in the Z-direction may be slightly smaller than the height of the pillar electrode 121, so that the mechanical member 122 may still be effective as a warpage-suppressing member.

The electronic component 123 is embedded in the resin material 126. The electronic component 123 has a predetermined function, such as, for example, an IC, a bridge, a condenser, a capacitor, an inductor, a coil, a thermistor, a resistor, a fuse, and the like. The electronic component 123 may be, for example, a semiconductor chip, and may be a bridge die, which may include wiring therein and may include additional circuit components. The interposer substrate 10 has an electronic component 123, so that a desired function may be imparted to the interposer connecting the electronic devices 31 and 32 and the mounting substrate 20. Accordingly, it becomes possible to realize miniaturization and high functionality of the module 1. The constituent material of the electronic component 123 is different from that of the resin material 126. The elastic modulus of the electronic component 123 is different from that of the resin material 126. The thickness (size in the Z-direction) of the electronic component 123 is smaller than that of the resin layer 12. As can be seen, the electronic component 123 may be embedded in the resin layer 12 and therefore embedded in the interposer substrate 10.

An adhesive layer 125 provided between the electronic component 123 and the first redistribution layer 11 plays a role in adhering the electronic component 123 to the first redistribution layer 11. A region surrounding the adhesive layer 125 is covered with a resin material 126.

According to some embodiments, the adhesive layer 125 includes an organic insulating material such as, for example, an epoxy resin, a phenol resin, an acrylic resin, a polyimide resin, and a liquid crystal polymer. The adhesive layer 125 may also include a filler. In some embodiments, a coefficient of linear expansion of the adhesive layer 125 is lower than a coefficient of linear expansion of the resin material 126. Accordingly, it becomes possible to suppress warping of the interposer substrate 10. In some embodiments, the thermal conductivity of the adhesive layer 125 is higher than thermal conductivity of the resin material 126. Accordingly, it becomes possible to improve heat dissipation properties of the interposer substrate 10.

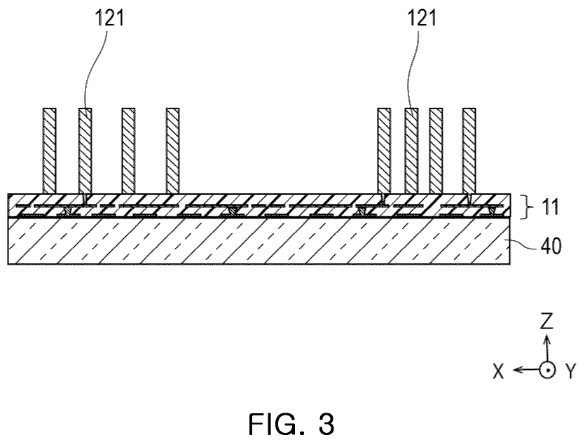

Next, an example of a manufacturing method of module 1 is described using FIGS. 3 to 9. First, a first redistribution layer 11 and a pillar electrode 121 are formed in this order on a support substrate 40 (FIG. 3). The support substrate 40 is comprised of a plate-shaped member including, for example, at least one of glass, silicon (Si), SUS (Stainless Used Steel), ferrite, alumina, and prepreg. A glass, for example, may provide a desirable coefficient of thermal expansion and surface smoothness. A first adhesion layer, a second adhesion layer, a peeling layer, a first seed layer, and a second seed layer may be provided from a side of the support substrate 40 between the support substrate 40 and the first redistribution layer 11.

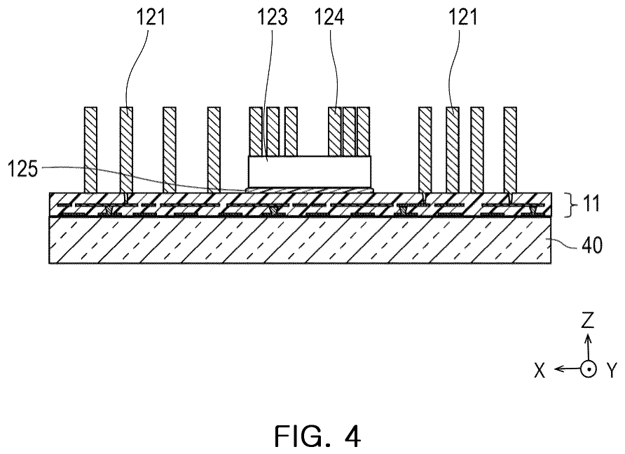

After forming the pillar electrode 121, an electronic component 123 is mounted on the first redistribution layer 11. Thereafter, a plurality of pillar electrodes 124 are formed on the electronic component 123 (FIG. 4). The electronic component 123 is adhered to the first redistribution layer 11 using an adhesive layer 125. The adhesive layer 125 may be provided on the electronic component 123, or may be provided on the first redistribution layer 11. The adhesive layer 125 may be in any shape, such as a paste or film, but as an example, an adhesive layer 125 in a paste shape is preferably used.

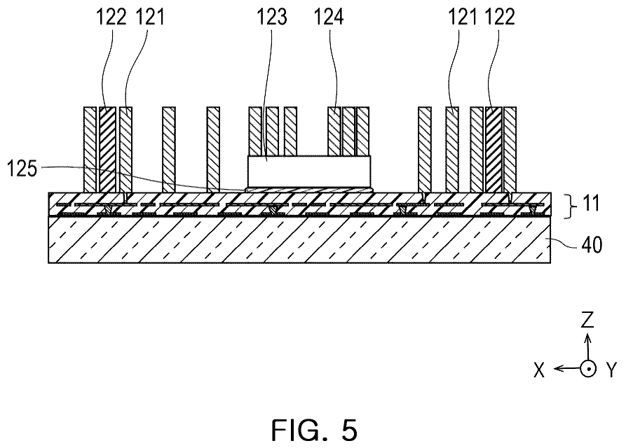

After forming the pillar electrode 124, the mechanical member 122 is formed (FIG. 5). The mechanical member 122 is adhered to the first redistribution layer 11 using, for example, an adhesive.

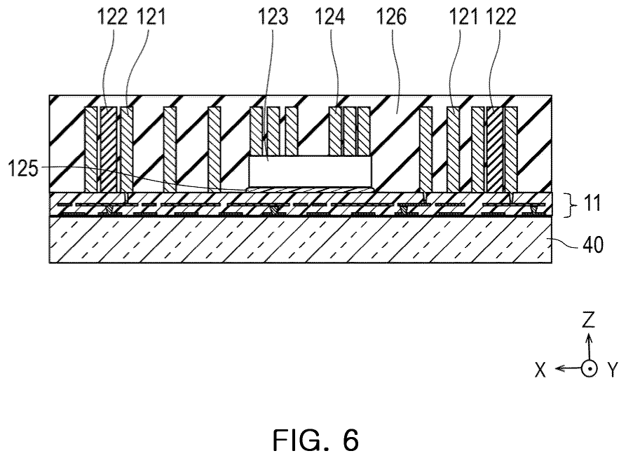

Next, a resin material 126 is prepared on the first redistribution layer 11 to cover the pillar electrodes 121 and 124 and electronic components 123 (FIG. 6). For example, the resin material 126 may be prepared using a film lamination method or a spin coating method.

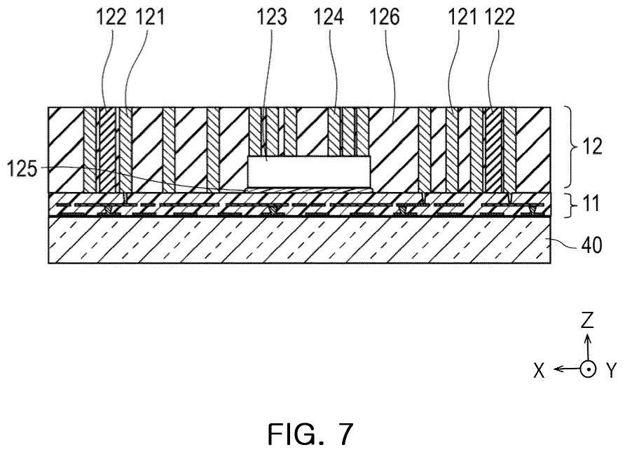

Subsequently, the resin material 126 is planarized (FIG. 7). For example, the resin material 126 may be flattened using a Chemical Mechanical Polishing (CMP) method. By flattening the resin material 126 until the pillar electrodes 121 and 124 are exposed, the resin layer 12 is formed.

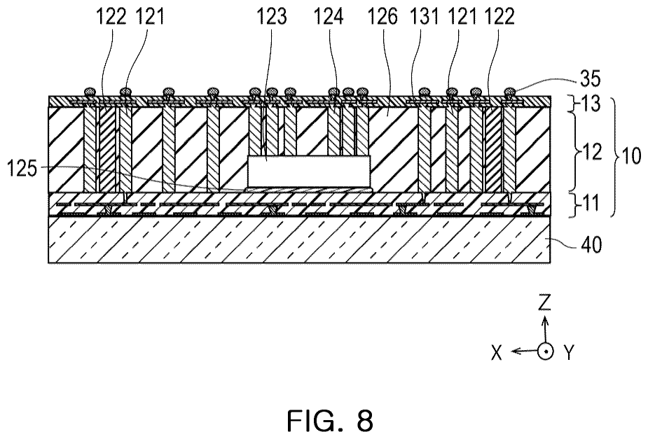

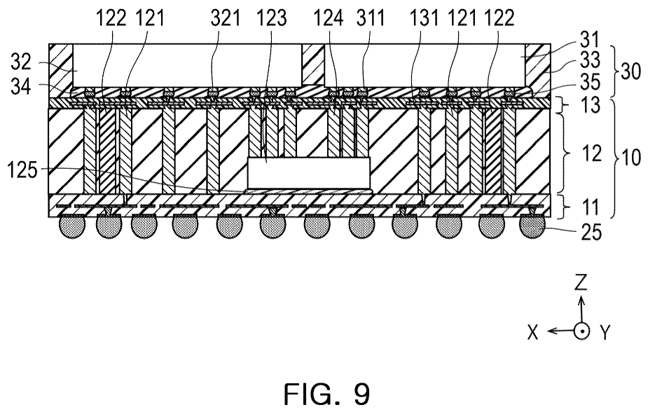

After forming the resin layer 12, a second redistribution layer 13 and bumps 35 are formed in this order on the resin layer 12 (FIG. 8). Thereafter, an electronic device layer 30 and bumps 25 are formed (FIG. 9). The electronic device layer 30 and the bumps 25 are formed, for example, as follows.

First, electronic devices 31 and 32 are mounted on the second redistribution layer 13 by the bumps 35. For example, the electronic devices 31 and 32 may be placed on the bumps prior to reflow, and a reflow process may be performed to result in the bumps that form connection terminals. In this case, subsequently, an underfill material 34 is formed between the electronic devices 31 and 32 and the interposer substrate 10 to fill spaces between the bumps. Next, an encapsulating material 33 is formed to cover the electronic devices 31 and 32. For example, a thickness of the sealing material 33 may be adjusted by polishing, or the like.

Subsequently, the support substrate 40 is removed. Next, a connection terminal such as bump 25 is formed by connecting the same to the wiring 111 of the first redistribution layer 11. Accordingly, an electronic device layer 30 and a bump 25 are formed. Thereafter, a module 1 may be formed by connecting the mounting substrate 20 to the interposer substrate 10 by the bumps 25. An additional reflow process may be performed to reflow the bumps 25 to form the connection terminals.

The interposer substrate 10 and the module 1 of the present embodiment has a mechanical member 122. The mechanical member 122 has a Young's modulus higher than that of a resin material 126. Accordingly, the influence of internal stress in the interposer substrate 10 is reduced compared to the case in which no mechanical member is provided on the interposer substrate. Therefore, warpage of the interposer substrate 10, particularly due to heat during reflow, operation, or other heating events, may be suppressed. Hereinafter, this operational effect is explained.

When the interposer substrate has a layer of a resin material, the amount of warpage tends to increase with changes in temperature as compared to when the interposer substrate has a layer of an inorganic material. This is because resin materials having relatively low Young's modulus are easily affected by internal stress. If warpage occurs in the interposer substrate due to this internal stress during the manufacturing and use of the module, there may be a risk that a problem may occur in an electrical connection between the mounting substrate and the electronic device layer, thereby reducing the reliability of the module.

In contrast thereto, in the interposer substrate 10 of the present embodiment, since the mechanical member 122 is provided in the resin layer 12, the influence of internal stress is reduced. Accordingly, the warpage of the interposer substrate 10 during manufacturing and use is suppressed, and the connection reliability in the module 1 may be improved.

In addition, since the mechanical member 122 is electrically insulated from each electrical component of the module 1, the shape, number, position, and the like of the mechanical member 122 may be easily changed. Therefore, a degree and direction of warpage of the interposer substrate 10 may be freely adjusted, thereby improving a degree of freedom in the design of the module 1.

As described above, the interposer substrate 10 and the module 1 of the present embodiment have a mechanical member 122 having a Young's modulus higher than that of the resin material 126. The Young's modulus of the mechanical member 122 may be, for example, between 2 and 500 times the Young's modulus of the resin material, and in some cases, between 10 and 200 times the Young's modulus of the resin material. Accordingly, the influence of internal stress in the interposer substrate 10 becomes smaller. Therefore, the warpage of the interposer substrate 10 may be suppressed.

Hereinafter, a modified example of the interposer substrate 10 according to the embodiment described above is described. Hereinafter, in order to avoid duplication of explanation, a detailed description of the same configuration as the interposer substrate 10 of embodiment described above will be omitted.

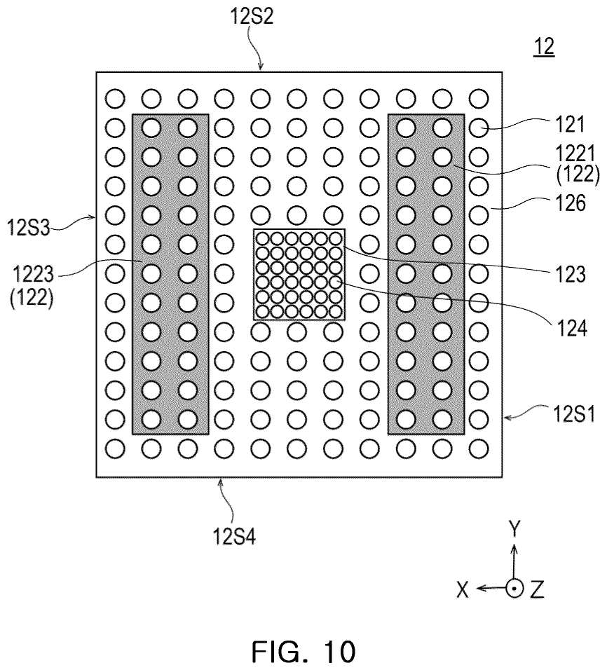

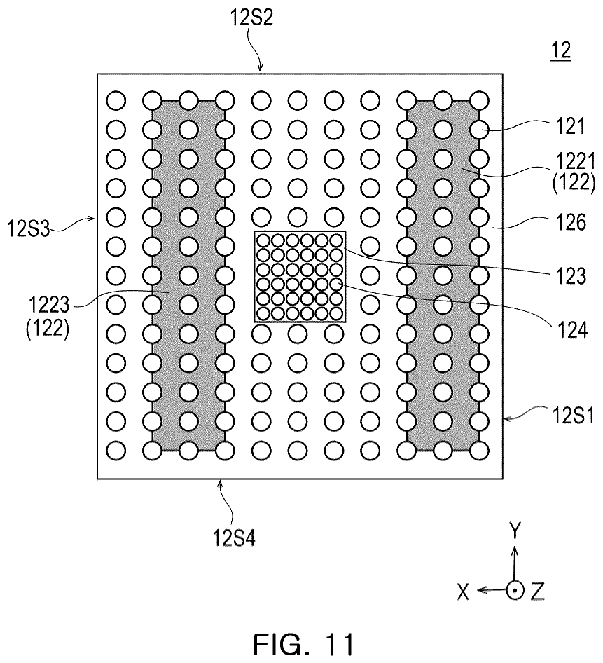

FIGS. 10 and 11 illustrate an example of a planar configuration of a resin layer 12 according to a modified example. FIGS. 10 and 11 correspond to FIG. 2 described in this embodiment. For example, the mechanical member 122 does not have to be provided near all sides (sides 12S1, 12S2, 12S3, and 12S4). For example, among the sides 12S1, 12S2, 12S3, and 12S4, a mechanical member 122 may be provided in the vicinity of (e.g., adjacent to) each of the two opposing sides 12S1 and 12S3 (e.g., two opposite side edges).

For example, a first mechanical member 1221 and a third mechanical member 1223 extending in a Y-direction may be provided between the adjacent pillar electrodes 121 in the Y-direction. The disposition, size, and shape of the mechanical member 122 may be freely modified.

The configuration of the interposer substrate 10 described above is a description of the main configuration in explaining the features of the above-described embodiment, and is not limited to the configuration described above, and can be modified in various manners within the scope of the patent claims. In addition, it does not exclude the configuration that a general interposer substrate may have.

For example, the interposer substrate 10 may have one mechanical member 122, or may have three or five or more mechanical members 122. The mechanical member 122 may be disposed in a location other than the peripheral portion of the resin layer 12, or may be disposed, for example, in a central portion thereof in a manner that still suppresses warpage.

The mechanical member 122 may have a shape other than that shown in FIG. 2, or the like. The mechanical member 122 may have, for example, a number of components having a spherical or cylindrical shape.

The interposer substrate 10 may have additional connection vias or connection vias instead of pillar electrodes 121 and 124, which connection vias are formed after forming the resin material 126. In this case, the conductors extending from a top surface of the resin material 126 to the bottom surface of the resin material 126 may be formed of a conductive film or the like that forms the connection via.

As set forth above, according to aspects of the present inventive concept, an interposer substrate and a module has a mechanical member having a Young's modulus higher than that of the first resin material. Accordingly, the influence of internal stress in the interposer substrate is reduced. Therefore, warpage of the interposer substrate may be suppressed.

The various and beneficial advantages and effects of the present inventive concept are not limited to the above-described content, and may be more easily understood through description of specific embodiments of the present inventive concept.

While example embodiments have been illustrated and described above, it will be apparent to those skilled in the art that modifications and variations could be made without departing from the scope of the present invention as defined by the appended claims.

What is claimed is:

1. A semiconductor package comprising:
an interposer substrate between a mounting substrate and a semiconductor device, the interposer substrate comprising:
a plurality of conductors electrically connecting the mounting substrate to the semiconductor device;
a warpage-suppressing member electrically insulated from the mounting substrate, the semiconductor device, and the plurality of conductors; and
a first resin material surrounding the plurality of conductors and the warpage-suppressing member,
wherein the warpage-suppressing member has a Young's modulus higher than a Young's modulus of the first resin material.

2. The semiconductor package of claim 1, wherein the plurality of conductors is a plurality of conductive vias and the warpage-suppressing member includes a plurality of warpage-suppressing beams or a plurality of warpage-suppressing bars.

3. The semiconductor package of claim 1, wherein the first resin material contacts the plurality of conductors and the warpage-suppressing member.

4. The semiconductor package of claim 1, wherein the warpage-suppressing member has a Young's modulus of 70 GPa or more.

5. The semiconductor package of claim 1, wherein the warpage-suppressing member comprises at least one of ceramic and glass.

6. The semiconductor package of claim 5, wherein the ceramic comprises at least one of aluminum oxide, aluminum nitride, and silicon carbide.

7. The semiconductor package of claim 1, wherein the warpage-suppressing member extends along at least two sides of the interposer substrate.

8. The semiconductor package of claim 1,
wherein the plurality of the conductors are arranged side by side in a first direction and a second direction, intersecting the first direction, and
wherein the warpage-suppressing member includes a first warpage-suppressing member portion disposed between adjacent rows of the conductors in the first direction and extending in the second direction.

9. The semiconductor package of claim 8, wherein the warpage-suppressing member further comprises a second warpage-suppressing member portion disposed between adjacent rows of the conductors in the second direction and extending in the first direction.

10. The semiconductor package of claim 8, wherein the warpage-suppressing member is further disposed between adjacent rows of the conductors in the second direction.

11. The semiconductor package of claim 1, further comprising:
a bridge die between the mounting substrate and the semiconductor device, and electrically connecting the semiconductor device to an additional semiconductor device mounted horizontally adjacent to the semiconductor device.

12. The semiconductor package of claim 1, wherein, on a predetermined plane parallel to a main surface of the interposer substrate, an area occupied by the warpage-suppressing member is between 0.1% and 50% with respect to an area of the interposer substrate.

13. The semiconductor package of claim 1, wherein in a direction perpendicular to a main surface of the interposer substrate, a distance between a top surface and a bottom surface of the warpage-suppressing member is less than or equal to a distance between a top surface and a bottom surface of each conductor.

14. The semiconductor package of claim 13, further comprising a second resin material provided with the semiconductor device.

15. The semiconductor package of claim 1, further comprising:
a first redistribution layer between the interposer substrate and the mounting substrate and electrically connecting the mounting substrate to the plurality of conductors; and
a second redistribution layer between the interposer substrate and the semiconductor device and electrically connecting the semiconductor device to the plurality of conductors.

16. The semiconductor package of claim 15, wherein the semiconductor device is a first semiconductor device mounted on the second redistribution layer, and further comprising:
a second semiconductor device mounted on the second redistribution layer and horizontally adjacent to the first semiconductor device; and
a bridge die mounted on the first redistribution layer and electrically connecting the first semiconductor device to the second semiconductor device.

17. The semiconductor package of claim 16, wherein:
the warpage-suppressing member includes a plurality of warpage-suppressing member portions, each extending along a respective side edge of the interposer substrate.

18. A semiconductor package, comprising:
a mounting substrate;
a first semiconductor device and a second semiconductor device on the mounting substrate;
an interposer between the mounting substrate and the first semiconductor device; and
a bridge die in the interposer and connecting the first semiconductor device to the second semiconductor device,
wherein the interposer includes an interposer substrate, a first redistribution layer between the mounting substrate and the interposer substrate, and a second redistribution layer between the first semiconductor device and the interposer substrate, and
wherein the interposer substrate includes:
a resin extending between the first redistribution layer and the second redistribution layer;
a plurality of conductive vias, each extending from the first redistribution layer to the second redistribution layer; and
a warpage-suppressing member including a plurality of elongated portions, each elongated portion extending vertically between the first redistribution layer and the second redistribution layer and extending horizontally along a top surface of the first redistribution layer.

19. The semiconductor package of claim 18, wherein the first semiconductor device is a memory chip or stack of memory chips, and the second semiconductor device is a logic device.

20. A semiconductor package comprising:
an interposer including:
an interposer substrate, a first redistribution layer on a bottom surface of the interposer substrate, and a second redistribution layer on a top surface of the interposer substrate, wherein:
the interposer substrate includes:
a first material layer extending between the first redistribution layer and the second redistribution layer;
a plurality of conductive vias, each extending from the first redistribution layer to the second redistribution layer and passing through the first material layer; and
a warpage-suppressing member passing through the first material layer and including a plurality of elongated portions, each elongated portion extending vertically between the first redistribution layer and the second redistribution layer and extending horizontally along a top surface of the first redistribution layer,
wherein a Young's modulus of the first material layer is lower than a Young's modulus of the warpage-suppressing member.
